(19) United States
(12) Patent Application Publication
(10) Pub. No.: US 2019/0279935 A1
(43) Pub. Date: Sep. 12, 2019

(54) SEMICONDUCTOR PACKAGE HAVING PACKAGE SUBSTRATE CONTAINING NON-HOMOGENEOUS DIELECTRIC LAYER

(71) Applicant: Intel Corporation, Santa Clara, CA (US)

(72) Inventors: David Allen UNRUH, JR., Chandler, AZ (US); Srinivas V. PIETAMBARAM, Chandler, AZ (US); Rahul N. MANEPALLI, Chandler, AZ (US)

(21) Appl. No.: 16/349,932

(22) PCT Filed: Dec. 29, 2016
(86) PCT No.: PCT/US2016/069314

§ 371 Date: May 14, 2019

(51) Int. Cl. H01L 23/532; H01L 23/522; H01L 25/065; H05K 1/09; H05K 1/18; H01L 23/00

(52) U.S. Cl. CPC H01L 23/5329; H01L 23/5226; H01L 25/0655; H05K 1/09; H05K 1/181; H01L 2224/73257; H01L 24/17; H01L 24/49; H01L 24/73; H05K 2201/0137; H05K 2201/10734; H01L 24/09

(57) ABSTRACT

Semiconductor packages including package substrates having non-homogeneous dielectric layers, and methods of fabricating such semiconductor packages, are described. In an example, a semiconductor package substrate includes a dielectric layer having a resin-rich region, e.g., a resin-rich sublayer, and a filler-rich region, e.g., a filler-rich sublayer. The sublayers may contain respective mixtures of an organic resin material and an inorganic filler material. The filler-rich sublayer may have a higher density of the inorganic filler material than the resin-rich sublayer. A density of the inorganic filler material may be lesser near a top surface of 0 the dielectric layer in which an electrical interconnect is embedded. The electrical interconnect may have a greater adhesion affinity to the organic resin material than the inorganic filler material, and thus, the electrical interconnect may readily attach to the functionally-graded dielectric layer.

### TECHNICAL FIELD

Embodiments are in the field of integrated circuit packages and, in particular, semiconductor packages having package substrates incorporating dielectric films.

### BACKGROUND

Multi-chip packages (MCP) include several silicon chips placed in a single semiconductor package. Typical interconnection strategies of MCPs include system-in-package, package-on-package, and three-dimensional integrated circuit architectures, to name a few. In any of these cases, as in other integrated circuit packaging types, one or more silicon chips are mounted on a package substrate. The package substrate generally includes several layers of electrical interconnects, e.g., input/output (IO) routing, attached to a dielectric film.

IO routing can be adhered to the dielectric film of the package substrate using several methods. For example, mechanical adhesion can be achieved by roughening an electrical interconnect of the IO routing, e.g., via chemical etching, to promote adhesion to the dielectric film. Similarly, prior to laminating the dielectric film on the electrical interconnect, chemical adhesion promotors of either an organic or an inorganic nature, e.g., silicon nitride, can be deposited on the electrical interconnect, e.g., via spray deposition, dip coating, or plasma-enhanced chemical vapor deposition, to promote adhesion between the dielectric film and the electrical interconnect.

### BRIEF DESCRIPTION OF THE DRAWINGS

FIG. 1 illustrates a cross-sectional view of a semiconductor package assembly, in accordance with an embodiment.

FIG. 2 illustrates a cross-sectional view of a non-homogeneous dielectric layer of a semiconductor package, in accordance with an embodiment.

FIG. 3 illustrates a cross-sectional view of a non-homogeneous dielectric layer of a semiconductor package, in accordance with an embodiment.

FIG. 4 illustrates a cross-sectional view of a layer of a build-up laminate of a semiconductor package, in accordance with an embodiment.

FIG. 5 illustrates a cross-sectional view of a layer of a build-up laminate of a semiconductor package, in accordance with an embodiment.

FIG. 6 illustrates a method of fabricating a semiconductor package including a package substrate having a non-homogeneous dielectric layer, in accordance with an embodiment.

FIGS. 7A-7E illustrate operations in a method of fabricating a semiconductor package including a package substrate having a non-homogeneous dielectric layer, in accordance with an embodiment.

FIG. 8 is a schematic of a computer system, in accordance with an embodiment.

### DESCRIPTION OF EMBODIMENTS

Semiconductor packages including package substrates having non-homogeneous dielectric layers, and methods of fabricating such semiconductor packages, are described. In the following description, numerous specific details are set forth, such as packaging and interconnect architectures, in order to provide a thorough understanding of embodiments. It will be apparent to one skilled in the art that embodiments may be practiced without these specific details. In other instances, well-known features, such as specific semiconductor fabrication processes, are not described in detail in order to not unnecessarily obscure embodiments. Furthermore, it is to be understood that the various embodiments shown in the Figures are illustrative representations and are not necessarily drawn to scale.

Future generations of package substrates may require significantly higher IO routing density than can be currently achieved. For example, more than 100 IO lines per mm per layer of a package substrate may be needed to achieve IO signaling goals. The current line spacing regime includes a line width of 9 μm and a line pitch of 12 μm, known as 9/12 μm L/S in the art. An IO density limit for a 9/12 μm L/S is less than 20 IO lines per mm per layer. To achieve increased density of IO routing of package substrates, advances in patterning, alignment, and electrical via formation may be necessary. For example, to achieve more than 100 IO lines per mm per layer of a package substrate, routing pitch may be reduced to a line width of 2 μm and a line pitch of 2 μm. Such a pattern is known as 2/2 μm L/S in the art. As IO routing shrinks to a 2/2 μm L/S pattern, however, mechanical roughening to adhere electrical interconnects of the IO routing to dielectric films of the package substrate may fail. More particularly, the reduced IO routing size may make mechanical roughening techniques infeasible due to an inability to lose copper material without sacrificing IO function. Surface modification of the electrical interconnects to achieve bonding between the electrical interconnects and dielectric layers is untested in the 2/2 L/S size regime, and may require processing conditions incompatible with organic packaging operations, such as operations performed at high temperature or under vacuum.

In an aspect, a semiconductor package includes a package substrate having an electrical interconnect of IO routing adhered to a dielectric layer having a non-homogeneous composition. More particularly, the dielectric layer may be a functionally-graded dielectric film having a polymer-rich or resin-rich material in proximity to a copper material of the electrical interconnect. A filler-rich material of the film may be separated from the copper material by the resin-rich material. The grading of the non-homogeneous film may be adjusted to maintain a bulk property of the dielectric layer in line with the bulk property of a dielectric film having a homogenous organic polymer/inorganic filler composite. The electrical interconnect may have an improved adhesive affinity to the resin-rich material, as compared to the filler-rich material, and thus, the dielectric layer may adhere to IO routing having micro fine line spacing more effectively than a dielectric film having a homogeneous organic polymer/inorganic filler composite, without compromising the bulk properties of the film. Furthermore, such adherence may be achieved without mechanical roughening of the electrical interconnect, i.e., without copper loss, and by simple, low-cost manufacturing methods, as described below.

Referring to FIG. 1, a sectional view of a semiconductor package assembly is illustrated in accordance with an embodiment. A semiconductor package assembly 100 may include one or more semiconductor packages 102 having semiconductor die(s) 104. For example, semiconductor package 102 may be a multi-chip package having several semiconductor dies 104 mounted on a package substrate 106.

Semiconductor die(s) 104 may be electrically connected to each other or to external components by intervening structures, such as electrical interconnects 108. Electrical interconnects 108 may, for example, be incorporated in a build-up laminate 110 of package substrate 106. More particularly, electrical interconnects 108 may include copper traces embedded and/or attached to one or more dielectric layers 112 of build-up laminate 110. Electrical interconnects 108 may be electrically connected to other interconnect structures of dielectric layer 112, such as microvias. Accordingly, semiconductor die 104 may be electrically connected to electrical interconnect 108 through one or more intervening interconnect structures, and furthermore, semiconductor die 104 may be electrically connected to other components, such as a second semiconductor die 113 or a printed circuit board assembly 114 of semiconductor package assembly 100, through electrical interconnect 108.

In an embodiment, semiconductor package 102 is mounted on printed circuit board 114 to form semiconductor package assembly 100. Electrical interconnections between semiconductor die 104, package substrate 106, and printed circuit board 114 may include solder balls 116 and or other metallic bump, trace, or wire interconnects, e.g., wire bonds between semiconductor die 104 and electrical contacts on package substrate 106. By way of example, semiconductor package 102 of semiconductor package assembly 100 may be a ball grid array (BGA) component having several solder balls 116 arranged in a ball field. That is, an array of solder balls 110 may be arranged in a grid or other pattern. Each solder ball 110 may be mounted and attached to a corresponding contact pad of printed circuit board 114. Printed circuit board 114 may be a motherboard or another printed circuit board of a computer system or device, e.g., a server or a workstation. Printed circuit board 114 may include signal routing to external device connectors (not shown). Accordingly, the solder ball and contact pad attachments may provide an electrical interface between semiconductor die(s) 104 of semiconductor package 102 and an external device.

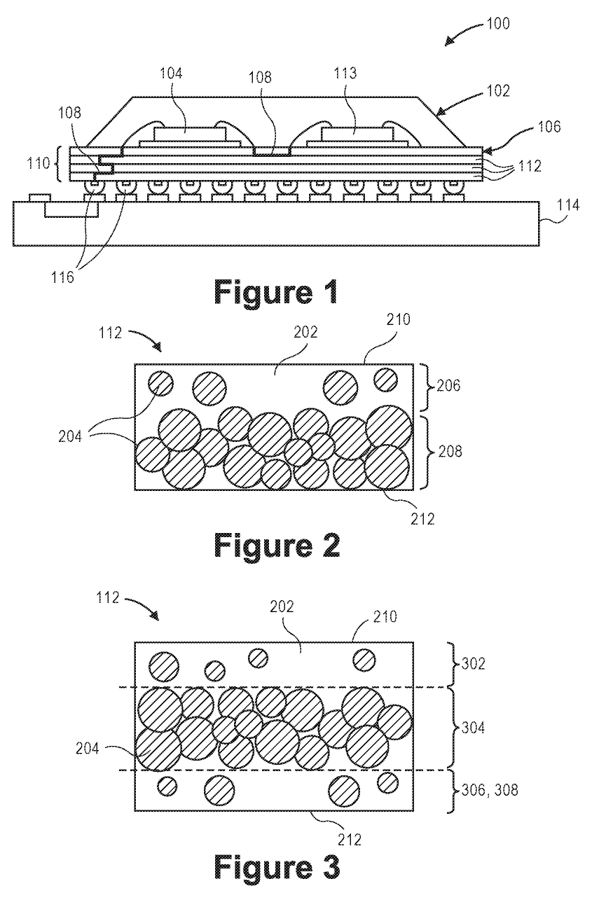

Referring to FIG. 2, a cross-sectional view of a non-homogeneous dielectric layer of a semiconductor package is shown in accordance with an embodiment. Poor adhesion between electrical interconnect materials, e.g., copper, and dielectric films is typically due to poor adhesion between the electrical interconnect material and inorganic filler components of the dielectric films. More particularly, the electrical interconnect materials ordinarily have better adhesive affinity to an organic resin material of the dielectric films than to the inorganic filler materials 204 of the dielectric films. Furthermore, a rigidity of the dielectric films can influence a bond strength between the dielectric film and the electrical interconnect. Since the inorganic filler materials of the dielectric films are typically harder than the organic resin materials of the dielectric films, heavily-filled systems tend to have lower metal-to-dielectric interfacial strengths than lightly-filled systems. That is, by minimizing an amount of inorganic filler material at the location of the electrical interconnect, a more uniform surface energy at the metal-to-polymer interface may be achieved to improve adhesion of IO routing having micro fine line spacing.

In an embodiment, one or more dielectric layer 112 of build-up laminate 110 is a functionally-graded dielectric film. More particularly, dielectric layer 112 may include a mixture of an organic resin material 202 and an inorganic filler material 204. A ratio between organic resin material 202 and inorganic filler material 204 may vary throughout dielectric layer 112. For example, dielectric layer 112 may include a resin-rich region 206 and a filler-rich region 208 having different mixtures of organic resin material 202 and inorganic filler material 204. Resin-rich region 206 may have a first mixture of organic resin material 202 and inorganic filler material 204 at a first ratio to each other, and a filler-rich region 208 may have a second mixture of organic resin material 202 and inorganic filler material 204 at a second ratio to each other, different than the first ratio. A ratio of organic resin material 202 to inorganic filler material 204 may be higher in resin-rich region 206 than in filler-rich region 208. Thus, resin-rich region 206 may have a higher adhesive affinity to electrical interconnect material than filler-rich region 208.

Organic resin material 202 and inorganic filler material 204 may be selected from material types that are known in the art. For example, organic resin material 202 may be any known resin type, such as any epoxy, known to be used in the formation of build-up dielectric films for integrated circuit packaging. Similarly, inorganic filler material 204 may be any known filler type such as silicon oxide, barium sulfate, or other inorganic fillers known to be used in the formation of build-up dielectric films.

A density of inorganic filler material 204 in filler-rich region 208 may be higher than a density of inorganic filler material 204 in resin-rich region 206. By way of example, filler-rich region 208 may have a first density of inorganic filler material 204 of at least 50%. That is, the first density may be greater than 50%. For example, the first density may be in a range of 60-90%, e.g., 70%. By contrast, resin-rich region 206 may have a second density of inorganic filler material 204 of no more than 50%. That is, the second density may be less than 50%. For example, the second density may be in a range of 0-40%, e.g., 30%.

In an embodiment, a density of organic resin material 202 may fill a balance of a composite region of dielectric layer 112. For example, when filler-rich region 208 has a 70% density of inorganic filler material 204, filler-rich region 208 may have a 30% density of organic resin material 202. Organic resin material 202 and inorganic filler material 204 may not be the only constituents of dielectric layer 112, however, and when other materials are included in dielectric layer 112 the densities of organic resin material 202 and/or inorganic filler material 204 may be adjusted accordingly.

Resin-rich region 206 and filler-rich region 208 may be distinctly situated relative to each other within dielectric layer 112. More particularly, a gradient of dielectric layer 112 may be controlled to locate resin-rich region 206 in an area of dielectric film where electrical interconnect 108 is, or will be, attached. As described above, placement of resin-rich region 206 near electrical interconnects 108, e.g., copper traces, can promote adhesion between electrical interconnect 108 and dielectric layer 112. Accordingly, resin-rich region 206 may extend along a first side of dielectric layer 112, e.g., an upward facing side, where electrical interconnect 108 will attach. The upward facing side may be a top surface 210 of dielectric layer 112, and thus, resin-rich region 206 may include top surface 210. By contrast, filler-rich region 208 may extend along a second side of dielectric layer 112, opposite from the first side, to separate the majority of inorganic filler material 204 from electrical interconnect 108. The second side may be a bottom surface 212 of dielectric layer 112, and thus, filler-rich region 208 may include bottom surface 212.

Referring to FIG. 3, a cross-sectional view of a non-homogeneous dielectric layer of a semiconductor package is shown in accordance with an embodiment. Resin-rich region 206 and filler-rich region 208 may be sublayers of dielectric layer 112. For example, resin-rich region 206 may be a resin-rich sublayer 302 of dielectric layer 112, and filler-rich region 208 may be a filler-rich sublayer 304 of dielectric layer 112. The term sublayer may refer to a portion of dielectric layer 112 having an upper and a lower boundary extending in a lateral or transverse direction (orthogonal to a vertical direction or thickness of dielectric layer 112) to separate the portion from an adjacent portion of dielectric layer 112. For example, the horizontal dashed lines shown in FIG. 3 illustrate the upper and lower boundaries of filler-rich sublayer 304 of dielectric layer 112. The boundaries of the sublayers of dielectric layer 112 may not be discrete, in that the boundaries that separate the sublayers may not be recognizable under cross-section. That is, the composite materials of resin-rich sublayer 302 and filler-rich sublayer 304 may meld together along the upper boundary. Nonetheless, even though the boundaries may not be recognizable under cross-section, in an embodiment, the sublayers are recognizable. Each of the sublayers may be quantified as having different densities of inorganic filler material 204 using analytical tools, and a density gradient may be identifiable throughout dielectric layer 112, e.g., in a vertical direction, using such analytical tools that measure density per unit volume of material.

In an embodiment, dielectric layer 112 includes local regions of resin-rich material along both top surface 210 and bottom surface 212. More particularly, dielectric layer 112 may include a second resin-rich region 306, e.g., a second resin-rich sublayer 308, on an opposite side of filler-rich sublayer 304 from resin-rich sublayer 302. That is, filler-rich region 208, e.g., filler-rich sublayer 304, may be between resin-rich region 206, e.g., resin-rich sublayer 302, and second resin-rich region 306, e.g., second resin-rich sublayer 308. Accordingly, resin-rich sublayer 302 may include top surface 210 of dielectric layer 112 and the second resin-rich sublayer 308 may include bottom surface 212 of dielectric layer 112.

The terms region and sublayer as used throughout the description may indicate different structural characteristics. For example, a region may indicate a portion of dielectric layer 112 that is not necessarily planar. A region may be amorphous but nonetheless may have a boundary based on a difference in relative densities of inorganic filler material 204 as compared to surrounding regions. On the other hand, a sublayer may be a region having a planar shape. The planar shape may be flat, e.g., may have boundaries parallel to top surface 210 and bottom surface 212. Alternatively, the planar shape may have boundaries that follow curvilinear paths, e.g., to deform around an electrical interconnect, as described below.

As described above, each of the regions, e.g., sublayers, of dielectric layer 112 may have different mixtures of organic and inorganic materials. For example, second resin-rich region 306 may have a third mixture of organic resin material 202 and inorganic filler material 204. The third mixture may not only have a different density of inorganic filler material 204 than the mixture in resin-rich sublayer 302, but the types of organic and/or inorganic materials in resin-rich sublayer 302 and second resin-rich sublayer 308 may also be different. By way of example, resin-rich sublayer 302 may incorporate silicon oxide as an inorganic filler material 204, and second resin-rich sublayer 308 may instead incorporate barium sulfate as an inorganic filler material 204. Likewise, a type of inorganic filler material 204 in filler-rich sublayer 304 may be different than the type of inorganic filler material 204 in one or more of resin-rich sublayer 302 or second resin-rich sublayer 308.

The differences in material densities or material types of each sublayer may be selected and tuned to maintain an overall bulk property of dielectric layer 112 as compared to a dielectric layer 112 of a same thickness having a homogeneous mixture of organic and inorganic materials. The overall bulk properties of dielectric layer 112 include properties such as a coefficient of thermal expansion (CTE), a dielectric loss tangent, a glass transition temperature, or other material or physical properties of the bulk film. Any of these properties can be impacted by changes in an inorganic filler loading, and thus, if local concentrations of inorganic filler material 204 are skewed, the overall loading of dielectric layer 112 may be tuned to keep the bulk properties constant. For example, when a bulk property of dielectric layer 112 changes due to a decrease in density of inorganic filler material 204 along top surface 210 of dielectric layer 112, a density of inorganic filler material 204 within a middle region of dielectric layer 112 may be increased to offset the change in the bulk property.

To keep a bulk property of dielectric layer 112 constant, an overall volume of inorganic filler material may be greater within one region or sublayer of dielectric layer 112 as compared to another region or sublayer. For example, filler-rich sublayer 304 may be thicker than resin-rich sublayer 302 and/or second resin-rich sublayer 308. By way of example, filler-rich sublayer 304 may have a thickness in a range of 7-20 μm, and one or both of resin-rich sublayer 302 or second resin-rich sublayer 308 may have a thickness in a range of 1-5 μm. Accordingly, filler-rich sublayer 304 may be thicker than any resin-rich sublayer of dielectric layer 112, whether dielectric layer 112 has a bilayer structure (FIG. 2), a tri-layer structure (FIG. 3), or any other number of sublayers.

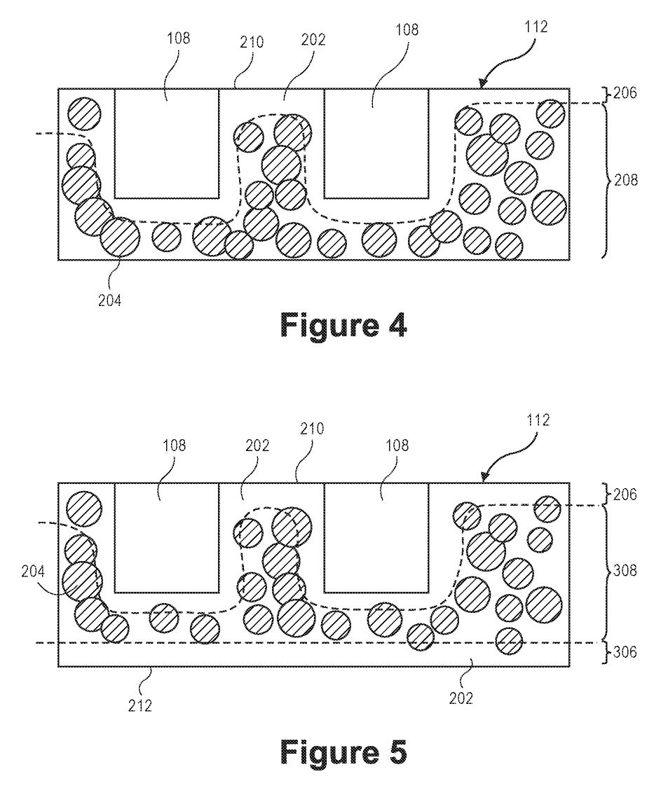

Referring to FIG. 4, a cross-sectional view of a layer of a build-up laminate of a semiconductor package is shown in accordance with an embodiment. Electrical interconnects 108 of package substrate 106 may be attached to dielectric layer 112 having a bilayer structure. For example, dielectric layer 112 may be laminated over electrical interconnects 108 to cover and/or encapsulate several sides of electrical interconnects 108. Thus, electrical interconnects 108 may become embedded within, and attached to, dielectric layer 112. Electrical interconnects 108 may, for example, include copper traces having a micro fine line spacing pattern. For example, electrical interconnects 108 may include IO routing having a 2/2 μm L/S pattern.

In an embodiment, electrical interconnect 108 is attached to resin-rich region 206 of dielectric layer 112. For example, electrical interconnect 108 may be embedded in resin-rich region 206 during a manufacturing operation, as described below. That is, dielectric layer 112 may be laminated over electrical interconnect 108 such that resin-rich region 206 surrounds covers several sides of electric interconnect 108 and electrical interconnect 108 thereby becomes embedded within resin-rich region 206. Laminating dielectric layer 112 over electrical interconnect 108 may cause the sublayers of dielectric layer 112 to flow and to form around electrical interconnect 108. Accordingly, the sublayers may not occupy strictly lateral or transverse planes within dielectric layer 112. The sublayers may follow curved contours. Resin-rich region 206 may be localized along top surface 210 of dielectric layer 112 and around sidewalls of electrical interconnect 108 on a first side of the dashed boundary line, and filler-rich region 208 may be localized on an opposite side of the dashed boundary line and separated from electrical interconnect 108 by resin-rich region 206. Accordingly, electrical interconnects 108 may attach to a region of dielectric layer 112 having a lower density of inorganic filler material 204 as compared to other portions of dielectric layer 112.

Referring to FIG. 5, a cross-sectional view of a layer of a build-up laminate of a semiconductor package is shown in accordance with an embodiment. Electrical interconnect 108 of package substrate 106 may be attached to dielectric layer 112 having a tri-layer structure. Electrical interconnects 108 may be attached to dielectric layer 112 having a tri-layer structure. In an embodiment, the electrical interconnect 108 is attached to resin-rich region 206 of dielectric layer 112. Resin-rich region 206 may extend along top surface 210 of dielectric layer 112 and around electrical interconnect 108, as described above. In the tri-layer structure, resin-rich region 206 may be separated from second resin-rich region 306 by filler-rich region 208. Second resin-rich region 306 may include bottom surface 212 of dielectric layer 112. Thus, additional electrical interconnects 108 may be attached to bottom surface 212. In such case, second resin-rich region 306 would separate the additional electrical interconnects 108 from the high-density inorganic filler material 204 of filler-rich region 208. Accordingly, electrical interconnects 108 may be attached to a region of dielectric layer 112 having a lower density of inorganic filler material 204 at one or both of top surface 210 or bottom surface 212.

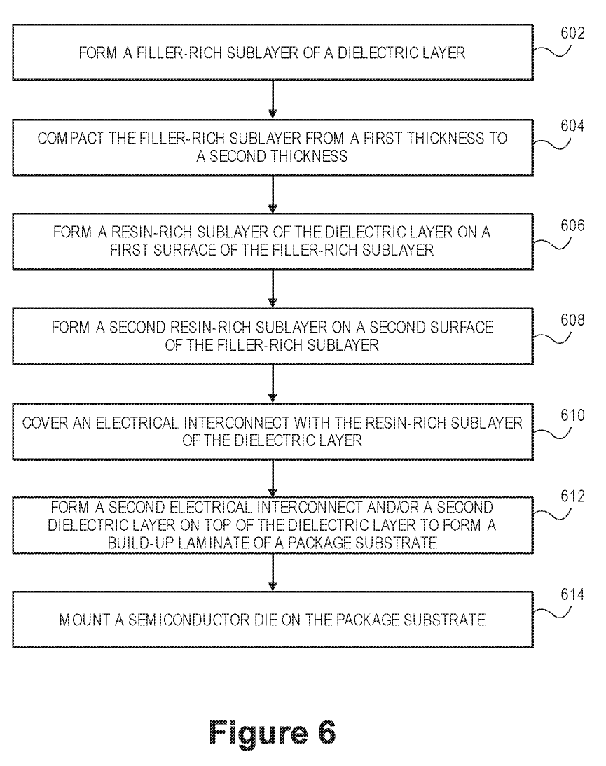

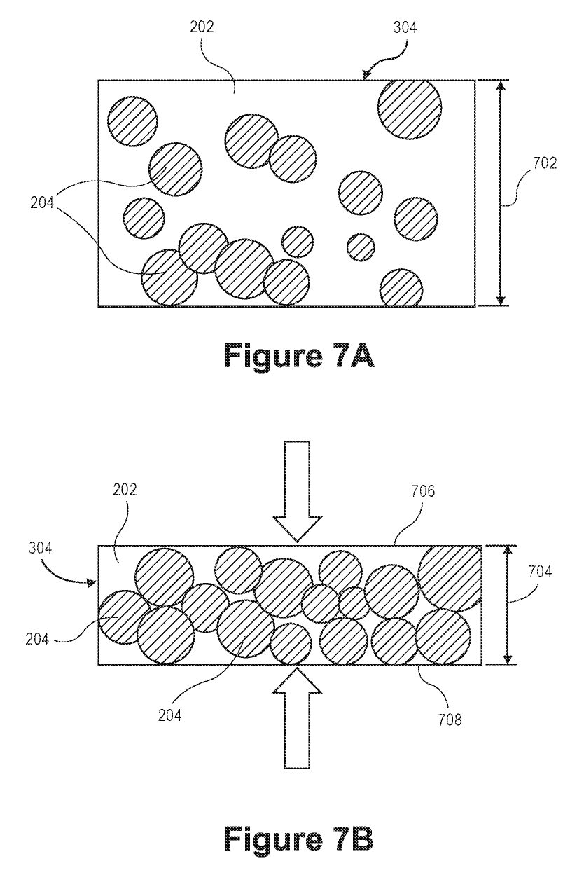

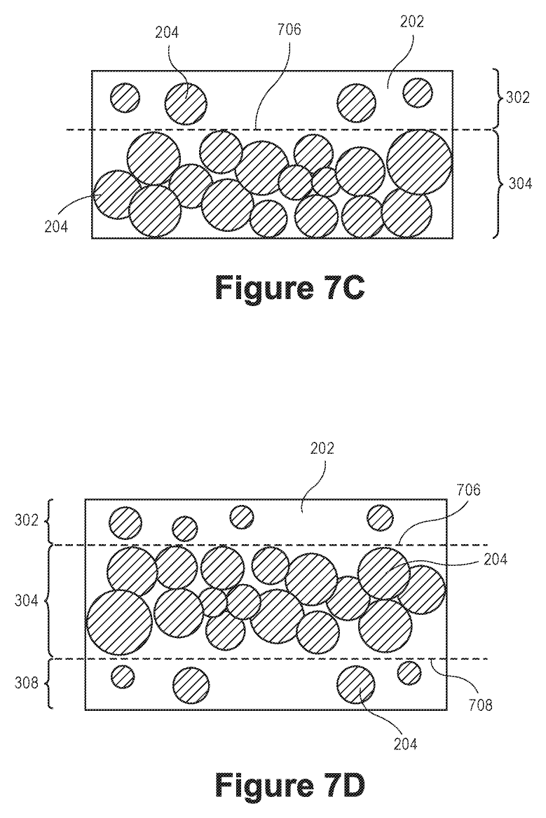

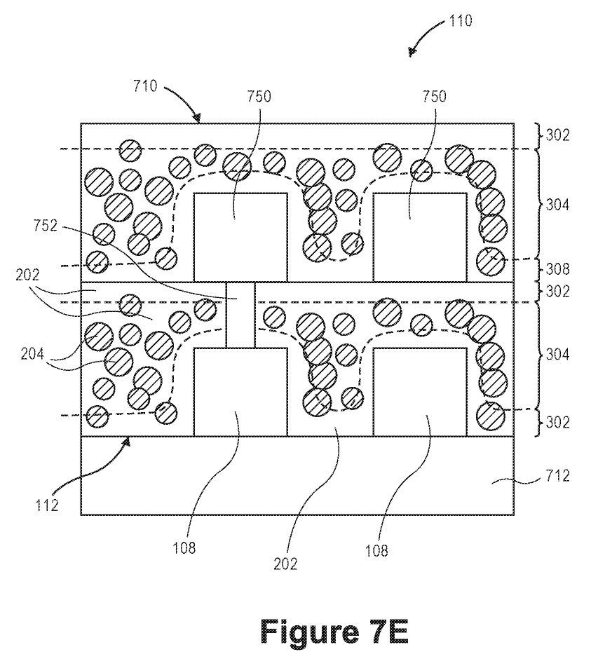

Referring to FIG. 6, a method of fabricating a semiconductor package including a package substrate having a non-homogeneous dielectric layer is shown in accordance with an embodiment. FIGS. 7A-7E illustrate operations in the method of FIG. 6, and thus, FIGS. 6-7E are described in combination below. Package substrate 106 having functionally-graded dielectric layer 112 can be manufactured using currently available, low-cost dielectric film manufacturing processes. These manufacturing processes may be integrated into a substrate build-up process as described below.

At operation 602, filler-rich sublayer of dielectric layer 112 may be formed. Referring to FIG. 7A, filler-rich sublayer may be formed by forming a first mixture of organic resin material 202 and inorganic filler material 204 on a receiving substrate to build a primary film. The first mixture may be deposited on a receiving substrate through conventional deposition means, such as the spraying of a varnish. The first mixture may include a solvent to form a solution including inorganic filler material 204 and organic resin material 202. The primary film may be a predicate of filler-rich sublayer 304, and may have a first thickness 702. In an embodiment, first thickness 702 is a thickness of filler-rich sublayer 304 in an uncompressed or uncompacted state, and may vary depending upon a final target film thickness. For example, first thickness 702 may be in a range of 7-20 μm. In the uncompacted state, filler-rich sublayer 304 may have a homogeneous mixture of organic resin material 202 and inorganic filler material 204. For example, the homogenous mixture may have a first density of inorganic filler material 204, e.g., a density of 10-40% inorganic filler material 204. The receiving substrate may be a carrier film, and after forming the uncompacted filler-rich sublayer 304 on the carrier film, the sublayer may be allowed to dry.

At operation 604, filler-rich sublayer 304 may be compacted from first thickness 702 to a second thickness 704. That is, filler-rich sublayer 304 may be compressed or otherwise transformed from the uncompacted state to a compacted state. In an embodiment, pressure is applied in opposite directions to a first surface 706 and a second surface 708 to squeeze filler-rich sublayer 304. The external force can be applied to both sides of filler-rich sublayer 304 using known processing equipment or processes, such as a hot press, roll-to-roll lamination, etc. Second thickness 704 may be a final target film thickness of filler-rich sublayer 304, i.e., a thickness of filler-rich sublayer 304 in the final dielectric layer 112 of package substrate 106. By way of example, second thickness 704 may be 6-19 μm. That is, second thickness 704 is less than first thickness 702. The density of inorganic filler material 204 may be higher in the compacted filler-rich sublayer 304 than in the uncompacted filler-rich sublayer 304. For example, the heat and/or pressure of compacting filler-rich sublayer 304 may cause the ratio of inorganic filler material 204 to organic resin material 202 to increase, e.g., from a density of 10-40% inorganic filler material 204 to a density of 60-90% inorganic filler material 204. Accordingly, the density of inorganic filler material 204 is higher in the compacted filler-rich sublayer 304 than in the uncompacted filler-rich sublayer 304.

At operation 606, resin-rich sublayer 302 may be formed on first surface 706 of filler-rich sublayer 304. Referring to FIG. 7C, resin-rich sublayer 302 may be deposited on filler-rich sublayer 304 using a similar process as described above for the formation of filler-rich sublayer 304. For example, resin-rich sublayer 302 may be sprayed on first surface 706. Resin-rich sublayer 302 may include a second mixture of organic resin material 202 and inorganic filler material 204. The second mixture may have a same or different composition than the first mixture used to form the uncompacted filler-rich sublayer 304. By way of example, the second mixture may include a same density of inorganic filler material 204 than the first mixture. Thus, filler-rich sublayer 304 in a compacted state may have a higher density of inorganic filler material 204 than resin-rich sublayer 302.

The secondary film, i.e., resin-rich sublayer 302, may be formed using processes different than those used to form filler-rich sublayer 304. For example, resin-rich sublayer 302 may be formed separately from filler-rich sublayer 304, and the separately formed sublayers may be laminated together. Accordingly, rather than being formed on filler-rich sublayer 304, resin-rich sublayer 302 may be bonded to filler-rich sublayer 304. By way of example, resin-rich sublayer 302 may be formed in a molding process, or by spraying the second mixture onto a respective carrier film, and the formed resin-rich sublayer 302 may be pressed against filler-rich sublayer 304 to merge the sublayers into a single structure.

At operation 608, a second resin-rich sublayer 308 may optionally be formed on second surface 708 of filler-rich sublayer 304. Operation 608 is optional because in an embodiment, dielectric layer 112 may have resin-rich region 206 on only one side of filler-rich region 208 (FIGS. 2 and 4). Referring to FIG. 7D, resin-rich sublayers, i.e., resin-rich sublayer 302 and second resin-rich sublayer 308, may be formed on both sides of filler-rich sublayer 304 through spraying of a solution or lamination of a pre-made film as described above. Resin-rich sublayer 302 and second resin-rich sublayer 308 may be formed on filler-rich sublayer 304 simultaneously or at different times. Thicknesses of resin-rich sublayer 302 and second resin-rich sublayer 308 may be the same or different. Both resin-rich sublayers 302, 308 may have a film thickness in a range of 1-5 μm. For example, resin-rich sublayer 302 may have a film thickness of 5 μm and second resin-rich sublayer 308 may have a film thickness of 2 μm. In either case, resin-rich sublayer 302 and second resin-rich sublayer 308 may be thinner than second thickness 704 of filler-rich sublayer 304. It will be appreciated from the description above that additional sublayers, i.e., filler-rich sublayers or resin-rich sublayers, may be incorporated into dielectric layer 112 and have a same or different thickness and density of inorganic filler material 204 as compared to any other sublayer of dielectric layer 112.

At operation 610, electrical interconnect 108 may be covered with resin-rich sublayer 302 of dielectric layer 112. Referring to FIG. 7E, electrical interconnects 108 may be disposed on a core layer 712 of build-up laminate 110. More particularly, a typical process flow (not shown) may be used to form electrical interconnects 108 on core layer 712. For example, a copper seed layer may be deposited on core layer 712, and the copper seed layer may be patterned and etched to reveal electrical interconnects 108. Such patterning and etching processes are well known, and thus, are not described at length here.

Dielectric layer 112 may be placed over electrical interconnects 108. More particularly, dielectric layer 112 may be laminated over core layer 712, and thus, electrical interconnects 108 may be sandwiched between dielectric layer 112 and core layer 712. During lamination, resin-rich sublayer 302 may deform around electrical interconnects 108 to surround several sides of electrical interconnects 108. Accordingly, electrical interconnects 108 may be referred to as being embedded within resin-rich sublayer 302. A majority of the material in contact with electrical interconnects 108 surfaces may be organic resin material 202. Accordingly, the resin-rich region may attach to electrical interconnect 108, and the filler-rich region may occupy a central portion of dielectric layer 112 between resin-rich sublayer 302 and second resin-rich sublayer 306.

At operation 612, a second electrical interconnect 750 and/or a second dielectric layer 710 may be formed on top of dielectric layer 112 to form build-up laminate 110 of package substrate 106. In an embodiment, second dielectric layer 710 is laminated over dielectric layer 112. Second dielectric layer 710 may have a respective resin-rich sublayer 302, filler-rich sublayer 304, and second resin-rich sublayer 308. In an embodiment, second electrical interconnects 750 may be formed over a top surface of dielectric 112. Formation of second electrical interconnects 750 may be performed using known processes, e.g., copper deposition, patterning, and etching. One or more second electrical interconnects 750 on top of dielectric layer 112 may be interconnected with one or more electrical interconnects 108 on core layer 712. For example, holes may be laser drilled through dielectric layer 112, and one or more electrical microvias 752 may be formed vertically through dielectric layer 112, as is known in the art. Second electrical interconnects 750 may then be patterned and/or plated on the microvias 752 above dielectric layer 112. Thus, microvia 752 may electrically connect electrical interconnect 108 with second electrical interconnect 752. Second dielectric layer 710 may be applied over upper surfaces of the electrical interconnects 108 on dielectric layer 112. For example, second dielectric layer 710 may be laminated on dielectric layer 112 to sandwich second electrical interconnects 750 between a top surface of dielectric layer 112 and a bottom surface of second dielectric layer 710. Thus, second electrical interconnects 750 may be encapsulated between resin-rich sublayers/regions 302, 308 of dielectric layer 112 and second dielectric layer 710. The encapsulated second electrical interconnects 750 may be surrounded on several sides by second resin-rich sublayer 308, and thus, may be referred to as being embedded within second resin-rich sublayer 308.

Referring to operation 614, one or more semiconductor dies 104 may be mounted on package substrate 106. For example, semiconductor die 104 may be soldered or otherwise bonded to an upper surface of dielectric layer 112. Electrical interconnects of semiconductor die 104, e.g., bonding wires or copper bumps, may be electrically connected to electrical interconnects 108 embedded within package substrate 106. Accordingly, semiconductor package 102 having functionally-graded dielectric films for enhanced adhesion of IO routing may be provided.

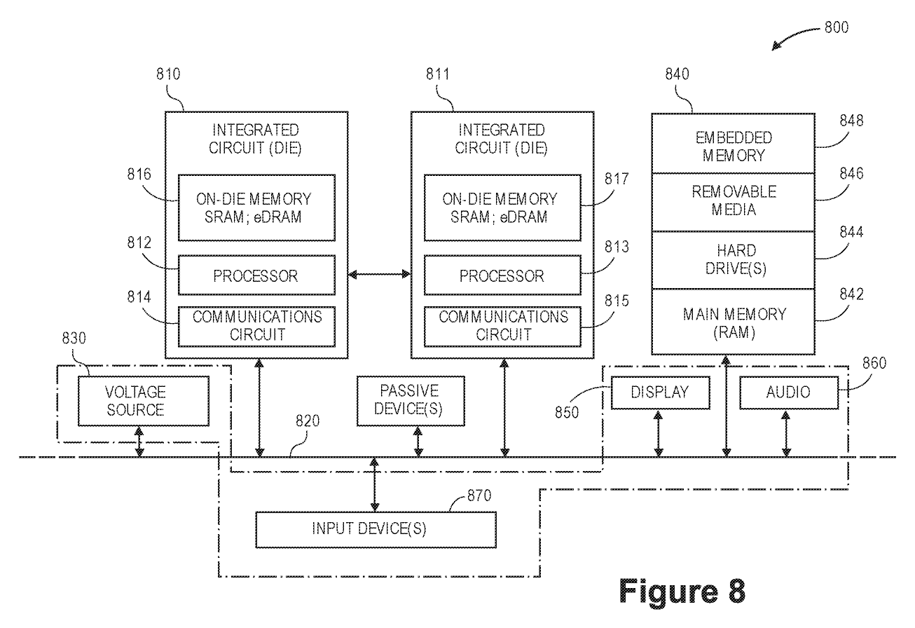

FIG. 8 is a schematic of a computer system, in accordance with an embodiment. The computer system 800 (also referred to as the electronic system 800) as depicted can embody a semiconductor package including a package substrate having a non-homogeneous dielectric layer, according to any of the several disclosed embodiments and their equivalents as set forth in this disclosure. The computer system 800 may be a mobile device such as a notebook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, a semiconductor package including a package substrate having a non-homogeneous dielectric layer, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 811 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, and an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including semiconductor package including a package substrate having a non-homogeneous dielectric layer, according to any of the several disclosed embodiments and their equivalents, an electronic system, a computer system, one or more methods of fabricating an integrated circuit, and one or more methods of fabricating an electronic assembly that includes a semiconductor package including a package substrate having a non-homogeneous dielectric layer, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor packages including package substrates having non-homogeneous dielectric layers and their equivalents. A foundation substrate may be included, as represented by the dashed line of FIG. 8. Passive devices may also be included, as is also depicted in FIG. 8.

Embodiments of semiconductor packages including package substrates having non-homogeneous dielectric layers are described above. In an embodiment, a semiconductor package has a package substrate including a build-up laminate having a dielectric layer. The dielectric layer includes a resin-rich region having a first mixture of an organic resin material and an inorganic filler material. The dielectric layer includes a filler-rich region having a second mixture of the organic resin material and the inorganic filler material. The filler-rich region has a higher density of the inorganic filler material than the resin-rich region. The semiconductor package includes a semiconductor die mounted on the package substrate.

In one embodiment, the semiconductor package includes an electrical interconnect attached to the resin-rich region of the dielectric layer. The semiconductor die is electrically connected to the electrical interconnect.

In one embodiment, the resin-rich region covers the electrical interconnect.

In one embodiment, the filler-rich region is a filler-rich sublayer of the dielectric layer. The resin-rich region is a resin-rich sublayer of the dielectric layer.

In one embodiment, the resin-rich sublayer includes a top surface of the dielectric layer.

In one embodiment, the dielectric layer includes a second resin-rich region having a third mixture of the organic resin material and the inorganic filler material. The filler-rich region is between the resin-rich region and the second resin-rich region.

In one embodiment, the second resin-rich region is a second resin-rich sublayer of the dielectric layer. The second resin-rich sublayer includes a bottom surface of the dielectric layer.

In one embodiment, the inorganic filler material in the filler-rich sublayer is a different type of inorganic filler material than the inorganic filler material in one or more of the resin-rich sublayer or the second resin-rich sublayer.

In one embodiment, the filler-rich sublayer is thicker than the resin-rich sublayer.

In one embodiment, the filler-rich sublayer has a first density of the inorganic filler material greater than 50%. The resin-rich region has a second density of the inorganic filler material less than 50%.

In an embodiment, a semiconductor package assembly includes a printed circuit board, and a semiconductor package mounted on the printed circuit board. The semiconductor package includes a package substrate including a build-up laminate having a dielectric layer. The dielectric layer includes a mixture of an organic resin material and an inorganic filler material. The dielectric layer has a resin-rich region and a filler-rich region. The filler-rich region has a higher density of the inorganic filler material than the resin-rich region. The semiconductor package assembly includes a semiconductor die mounted on the package substrate.

In one embodiment, the semiconductor package assembly includes an electrical interconnect attached to the resin-rich region of the dielectric layer. The semiconductor die is electrically connected to the printed circuit board through the electrical interconnect.

In one embodiment, the filler-rich region is a filler-rich sublayer of the dielectric layer. The resin-rich region is a resin-rich sublayer of the dielectric layer.

In one embodiment, the filler-rich sublayer is thicker than the resin-rich sublayer.

In one embodiment, the dielectric layer includes a second resin-rich region. The filler-rich region is between the resin-rich region and the second resin-rich region.

In an embodiment, a method of fabricating a semiconductor package including a package substrate having a non-homogeneous dielectric layer includes forming a filler-rich sublayer of a dielectric layer. The filler-rich sublayer includes a first mixture of an organic resin material and an inorganic filler material. The method includes forming a resin-rich sublayer of the dielectric layer on a first surface of the filler-rich sublayer. The resin-rich sublayer includes a second mixture of the organic resin material and the inorganic filler material. The filler-rich sublayer has a higher density of the inorganic filler material than the resin-rich sublayer.

In one embodiment, the method includes compacting the filler-rich sublayer from a first thickness to a second thickness. A density of the inorganic filler material is higher in the compacted filler-rich sublayer than in the uncompacted filler-rich sublayer.

In one embodiment, the method includes forming a second resin-rich sublayer on a second surface of the filler-rich sublayer.

In one embodiment, the resin-rich sublayer and the second resin-rich sublayer are formed on the filler-rich sublayer simultaneously.

In one embodiment, the method includes covering an electrical interconnect with the resin-rich sublayer of the dielectric layer. The method includes mounting a semiconductor die on a package substrate having the dielectric layer. The semiconductor die is electrically connected to the electrical interconnect.

What is claimed is:

1. A semiconductor package, comprising:
a package substrate including a build-up laminate having a dielectric layer, wherein the dielectric layer includes a resin-rich region having a first mixture of an organic resin material and an inorganic filler material, and a filler-rich region having a second mixture of the organic resin material and the inorganic filler material, and wherein the filler-rich region has a higher density of the inorganic filler material than the resin-rich region; and
a semiconductor die mounted on the package substrate.

2. The semiconductor package of claim 1 further comprising an electrical interconnect attached to the resin-rich region of the dielectric layer, wherein the semiconductor die is electrically connected to the electrical interconnect.

3. The semiconductor package of claim 2, wherein the resin-rich region covers the electrical interconnect.

4. The semiconductor package of claim 1, wherein the filler-rich region is a filler-rich sublayer of the dielectric layer, and wherein the resin-rich region is a resin-rich sublayer of the dielectric layer.

5. The semiconductor package of claim 4, wherein the resin-rich sublayer includes a top surface of the dielectric layer.

6. The semiconductor package of claim 5, wherein the dielectric layer includes a second resin-rich region having a third mixture of the organic resin material and the inorganic filler material, and wherein the filler-rich region is between the resin-rich region and the second resin-rich region.

7. The semiconductor package of claim 6, wherein the second resin-rich region is a second resin-rich sublayer of the dielectric layer, and wherein the second resin-rich sublayer includes a bottom surface of the dielectric layer.

8. The semiconductor package of claim 7, wherein the inorganic filler material in the filler-rich sublayer is a different type of inorganic filler material than the inorganic filler material in one or more of the resin-rich sublayer or the second resin-rich sublayer.

9. The semiconductor package of claim 4, wherein the filler-rich sublayer is thicker than the resin-rich sublayer.

10. The semiconductor package of claim 9, wherein the filler-rich sublayer has a first density of the inorganic filler material greater than 50%, and wherein the resin-rich region has a second density of the inorganic filler material less than 50%.

11. A semiconductor package assembly, comprising:
a printed circuit board; and
a semiconductor package mounted on the printed circuit board, the semiconductor package including
a package substrate including a build-up laminate having a dielectric layer, wherein the dielectric layer includes a mixture of an organic resin material and an inorganic filler material, wherein the dielectric layer has a resin-rich region and a filler-rich region, and wherein the filler-rich region has a higher density of the inorganic filler material than the resin-rich region, and
a semiconductor die mounted on the package substrate.

12. The semiconductor package assembly of claim 11 further comprising an electrical interconnect attached to the resin-rich region of the dielectric layer, wherein the semiconductor die is electrically connected to the printed circuit board through the electrical interconnect.

13. The semiconductor package assembly of claim 12, wherein the filler-rich region is a filler-rich sublayer of the dielectric layer, and wherein the resin-rich region is a resin-rich sublayer of the dielectric layer.

14. The semiconductor package assembly of claim 13, wherein the filler-rich sublayer is thicker than the resin-rich sublayer.

15. The semiconductor package assembly of claim 14, wherein the dielectric layer includes a second resin-rich region, and wherein the filler-rich region is between the resin-rich region and the second resin-rich region.

16. A method, comprising:
forming a filler-rich sublayer of a dielectric layer, wherein the filler-rich sublayer includes a first mixture of an organic resin material and an inorganic filler material; and
forming a resin-rich sublayer of the dielectric layer on a first surface of the filler-rich sublayer, wherein the resin-rich sublayer includes a second mixture of the organic resin material and the inorganic filler material, and wherein the filler-rich sublayer has a higher density of the inorganic filler material than the resin-rich sublayer.

17. The method of claim 16 further comprising compacting the filler-rich sublayer from a first thickness to a second thickness, wherein a density of the inorganic filler material is higher in the compacted filler-rich sublayer than in the uncompacted filler-rich sublayer.

18. The method of claim 16 further comprising forming a second resin-rich sublayer on a second surface of the filler-rich sublayer.

19. The method of claim 18, wherein the resin-rich sublayer and the second resin-rich sublayer are formed on the filler-rich sublayer simultaneously.

20. The method of claim 19 further comprising:
covering an electrical interconnect with the resin-rich sublayer of the dielectric layer; and
mounting a semiconductor die on a package substrate having the dielectric layer, wherein the semiconductor die is electrically connected to the electrical interconnect.
